(19) United States
(12) Patent Application Publication
(10) Pub. No.: US 2025/0279564 A1
(43) Pub. Date: Sep. 4, 2025

(54) COMPACT PHASE SHIFTER LAYOUT

(71) Applicant: Apple Inc., Cupertino, CA (US)

(72) Inventors: Bo Yu, San Diego, CA (US); Seyedmohammadreza Razavian, San Diego, CA (US); Zhengan Yang, Del Mar, CA (US); Haitao Cheng, San Jose, CA (US); Ali Parsa, Poway, CA (US); Zhang Jin, San Diego, CA (US)

(21) Appl. No.: 18/592,731

(22) Filed: Mar. 1, 2024

(51) Int. Cl. H01P 1/18; H01Q 1/24

(52) U.S. Cl. CPC H01P 1/18; H01Q 1/243

(57) ABSTRACT

This disclosure is directed to phase shifter circuitry with reduced insertion loss and/or reduced area compared to other phase shifter circuitry. The phase shifter circuitry may include a first phase shifter circuit and a second phase shifter circuit. The first phase shifter circuit may include two overlaid coils forming three inductors. Similarly, the second phase shifter circuit may include two overlaid coils forming three inductors. A coil of the first phase shifter circuit may be extended orthogonally to a coil of the second phase shifter. As such, the first phase shifter circuit and the second phase shifter circuit may have reduced undesired induced currents during operation. Moreover, the coils of each of the phase shifter circuits are disposed adjacently on multiple circuit layers to improve the insertion loss of the phase shifter circuitry, reduced the area occupied by the phase shifter circuitry, or both, among other things.

### BACKGROUND

The present disclosure relates generally to phase shifter circuitry of an electronic device.

Phase shifter circuitry may adjust a phase of input signals by a desired value. For example, an electronic device may include the phase shifter circuitry. The electronic device may generate transmission signals in the form of a beam with desired beam characteristics. The electronic device may adjust a phase of the transmission signals by the phase shifter circuitry based on a direction of the desired beam. The electronic device may then transmit the transmission signals as adjusted. Similarly, the electronic device may receive signals having desired beam characteristics. The electronic device may adjust a phase of the received signals by the phase shifter circuitry to receive the signals.

Restrictions in a layout of the phase shifter circuitry may result in reducing signal quality, decreased area occupied by the phase shifter circuitry, among other things. Improved phase shifter circuitry layouts are desired to improve the signal quality and/or reduce an area occupied by the phase shifter circuitry.

This section is intended to introduce the reader to various aspects of art that may be related to various aspects of the present disclosure, which are described and/or claimed below. This discussion is believed to be helpful in providing the reader with background information to facilitate a better understanding of the various aspects of the present disclosure. Accordingly, it should be understood that these statements are to be read in this light, and not as admissions of prior art.

### SUMMARY

A summary of certain embodiments disclosed herein is set forth below. It should be understood that these aspects are presented merely to provide the reader with a brief summary of these certain embodiments and that these aspects are not intended to limit the scope of this disclosure. Indeed, this disclosure may encompass a variety of aspects that may not be set forth below.

In one embodiment, phase shifter circuitry may include a first phase shifter circuit including a first coil and a second coil. The second coil may be disposed over and extended around a boundary of the first coil, and the second coil may include a first twisted loop conductor extended in a first direction. The phase shifter circuitry may also include a second phase shifter circuit including a third coil and a fourth coil. The fourth coil may be disposed over and enclosed by a boundary of the third coil, and the fourth coil may include a second twisted loop conductor extended in a second direction different than the first direction.

In another embodiment, phase shifter circuitry may include a first coil disposed on a first circuit layer and having a first boundary. The first coil may include a first polygonal conductor including a first inner conductor coupled to a second inner conductor. The first coil may also include a second polygonal conductor including a first outer conductor coupled to a second outer conductor. The first outer conductor may be coupled to the first inner conductor, the second outer conductor may be coupled to the second inner conductor, and the first polygonal conductor may be encircled by the second outer conductor. The phase shifter circuitry may also include a second coil disposed on a second circuit layer. The second coil may be coupled to the first inner conductor and the second inner conductor, and the second coil may include a first twisted loop conductor having a second boundary that covers the first boundary of the first coil. Additionally, the phase shifter circuitry may include a third coil disposed on the first circuit layer. The third coil may be coupled to the second outer conductor, and the third coil may not overlap with the first coil and the second coil. Further, the phase shifter circuitry may include a fourth coil coupled to the third coil. The fourth coil may include a second twisted loop conductor encircled by the third coil, and the second twisted loop conductor may be disposed in a different direction with respect to the first twisted loop conductor.

In yet another embodiment, an electronic device includes processing circuitry, an antenna, and phase shifter circuitry coupled to the antenna and the processing circuitry. The phase shifter circuitry may include a first coil and a second coil coupled to the first coil. The second coil may be disposed over and extend around the first coil, and the second coil may include a first twisted loop conductor extended in a first direction. The phase shifter circuitry may also include a third coil coupled to the first coil. The third coil may not overlap with the first coil and the second coil. Further, the phase shifter circuitry may include a fourth coil coupled to the third coil. The fourth coil may be disposed over and surrounded by the third coil, and the fourth coil may include a second twisted loop conductor extending in a second direction different than the first direction.

Various refinements of the features noted above may exist in relation to various aspects of the present disclosure. Further features may also be incorporated in these various aspects as well. These refinements and additional features may exist individually or in any combination. For instance, various features discussed below in relation to one or more of the illustrated embodiments may be incorporated into any of the above-described aspects of the present disclosure alone or in any combination. The brief summary presented above is intended only to familiarize the reader with certain aspects and contexts of embodiments of the present disclosure without limitation to the claimed subject matter.

### BRIEF DESCRIPTION OF THE DRAWINGS

Various aspects of this disclosure may be better understood upon reading the following detailed description and upon reference to the drawings in which:

FIG. 1 is a block diagram of an electronic device, according to embodiments of the present disclosure;

FIG. 2 is a functional diagram of the electronic device of FIG. 1, according to embodiments of the present disclosure;

FIG. 3 is a schematic diagram of a transmitter of the electronic device of FIG. 1, according to embodiments of the present disclosure;

FIG. 4 is a schematic diagram of a receiver of the electronic device of FIG. 1, according to embodiments of the present disclosure;

FIG. 5 is a schematic diagram of phase shifter circuitry of the electronic device of FIGS. 1-4, according to embodiments of the present disclosure;

FIG. 6 is a layout of a first phase shifter circuit of the phase shifter circuitry of FIG. 5, according to embodiments of the present disclosure;

FIG. 7 is a layout of a second phase shifter circuit of the phase shifter circuitry of FIG. 5, according to embodiments of the present disclosure; and

FIG. 8 is a layout of the phase shifter circuitry of FIGS. 6 and 7 including the first phase shifter circuit and the second phase shifter circuit, according to embodiments of the present disclosure.

### DETAILED DESCRIPTION OF SPECIFIC EMBODIMENTS

When introducing elements of various embodiments of the present disclosure, the articles “a,” “an,” and “the” are intended to mean that there are one or more of the elements. The terms “comprising,” “including,” and “having” are intended to be inclusive and mean that there may be additional elements other than the listed elements. Additionally, it should be understood that references to “one embodiment” or “an embodiment” of the present disclosure are not intended to be interpreted as excluding the existence of additional embodiments that also incorporate the recited features. Furthermore, the particular features, structures, or characteristics may be combined in any suitable manner in one or more embodiments. Use of the terms “approximately,” “near,” “about,” “close to,” and/or “substantially” should be understood to mean including close to a target (e.g., design, value, amount), such as within a margin of any suitable or contemplatable error (e.g., within 0.1% of a target, within 1% of a target, within 5% of a target, within 10% of a target, within 25% of a target, and so on). Moreover, it should be understood that any exact values, numbers, measurements, and so on, provided herein, are contemplated to include approximations (e.g., within a margin of suitable or contemplatable error) of the exact values, numbers, measurements, and so on. Additionally, the term “set” may include one or more. That is, a set may include a unitary set of one member, but the set may also include a set of multiple members.

This disclosure is directed to phase shifter circuitry with reduced insertion loss and/or reduced area compared to other phase shifters. The phase shifter circuitry may include, for example, a first phase shifter circuit and a second phase shifter circuit. In some embodiments, the first phase shifter circuit and the second phase shifter circuit may each include two coils forming three inductors.

The first phase shifter circuit and the second phase shifter circuit may each reduce induced currents of the phase shifter circuitry during operation. The first phase shifter circuit and the second phase shifter circuit may have non-overlapping boundaries. That is, the first phase shifter circuit and the second phase shifter circuit may each direct input signals through a number of polygonal conductors that are disposed adjacently or overlaid along multiple planes of a circuit board. The polygonal conductors of each of the first phase shifter circuit and the second phase shifter circuit may be non-overlapping or at least partially overlap with one another. The planes of the circuit board may be disposed in parallel to one another. In some cases, the induced currents of one or more of the polygonal conductors destructively combine to reduce induced currents of the phase shifter circuitry. As such, the phase shifter circuitry may output signals with improved linearity based on the reduced induced currents.

Moreover, the first phase shifter circuit and the second phase shifter circuit may each include orthogonally disposed figure-eight shaped polygonal conductors that are non-overlapping. In some cases, the orthogonal and non-overlapping disposition of the figure-eight shaped polygonal conductors may increase a distance between the polygonal conductors of the first phase shifter circuit and the second phase shifter circuit. The increased distance between the polygonal conductors may reduce the induced currents of the phase shifter circuitry.

In some embodiments, the phase shifter circuitry may have reduced insertion loss based on the reduction of the induced currents. In some cases, the phase shifter circuitry may output signals with improved linearity based on the reduced induced currents. Moreover, in specific embodiments, the phase shifter circuitry may have a reduced area compared to other phase shifters based on the disposition of the polygonal conductors of each of the inductors.

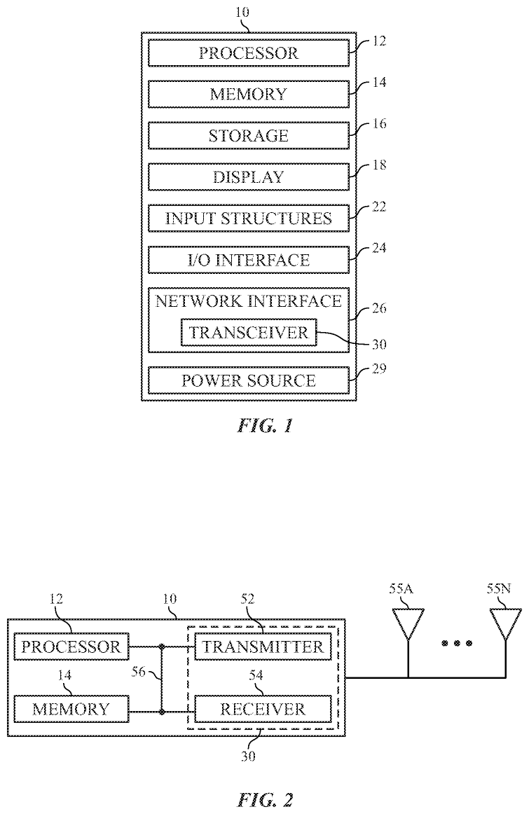

FIG. 1 is a block diagram of an electronic device 10, according to embodiments of the present disclosure. The electronic device 10 may include, among other things, one or more processors 12 (collectively referred to herein as a single processor for convenience, which may be implemented in any suitable form of processing circuitry), memory 14, nonvolatile storage 16, a display 18, input structures 22, an input/output (I/O) interface 24, a network interface 26, and a power source 29. The various functional blocks shown in FIG. 1 may include hardware elements (including circuitry), software elements (including machine-executable instructions) or a combination of both hardware and software elements (which may be referred to as logic). The processor 12, memory 14, the nonvolatile storage 16, the display 18, the input structures 22, the input/output (I/O) interface 24, the network interface 26, and/or the power source 29 may each be communicatively coupled directly or indirectly (e.g., through or via another component, a communication bus, a network) to one another to transmit and/or receive signals between one another. It should be noted that FIG. 1 is merely one example of a particular implementation and is intended to illustrate the types of components that may be present in the electronic device 10.

By way of example, the electronic device 10 may include any suitable computing device, including a desktop or notebook computer, a portable electronic or handheld electronic device such as a wireless electronic device or smartphone, a tablet, a wearable electronic device, and other similar devices. In additional or alternative embodiments, the electronic device 10 may include an access point, such as a base station, a router (e.g., a wireless or Wi-Fi router), a hub, a switch, and so on. It should be noted that the processor 12 and other related items in FIG. 1 may be embodied wholly or in part as software, hardware, or both. Furthermore, the processor 12 and other related items in FIG. 1 may be a single contained processing module or may be incorporated wholly or partially within any of the other elements within the electronic device 10. The processor 12 may be implemented with any combination of general-purpose microprocessors, microcontrollers, digital signal processors (DSPs), field programmable gate array (FPGAs), programmable logic devices (PLDs), controllers, state machines, gated logic, discrete hardware components, dedicated hardware finite state machines, or any other suitable entities that may perform calculations or other manipulations of information. The processors 12 may include one or more application processors, one or more baseband processors, or both, and perform the various functions described herein.

In the electronic device 10 of FIG. 1, the processor 12 may be operably coupled with a memory 14 and a nonvolatile storage 16 to perform various algorithms. Such programs or instructions executed by the processor 12 may be stored in any suitable article of manufacture that includes one or more tangible, computer-readable media. The tangible, computer-readable media may include the memory 14 and/or the nonvolatile storage 16, individually or collectively, to store the instructions or routines. The memory 14 and the nonvolatile storage 16 may include any suitable articles of manufacture for storing data and executable instructions, such as random-access memory, read-only memory, rewritable flash memory, hard drives, and optical discs. In addition, programs (e.g., an operating system) encoded on such a computer program product may also include instructions that may be executed by the processor 12 to enable the electronic device 10 to provide various functionalities.

In certain embodiments, the display 18 may facilitate users to view images generated on the electronic device 10. In some embodiments, the display 18 may include a touch screen, which may facilitate user interaction with a user interface of the electronic device 10. Furthermore, it should be appreciated that, in some embodiments, the display 18 may include one or more liquid crystal displays (LCDs), light-emitting diode (LED) displays, organic light-emitting diode (OLED) displays, active-matrix organic light-emitting diode (AMOLED) displays, or some combination of these and/or other display technologies.

The input structures 22 of the electronic device 10 may enable a user to interact with the electronic device 10 (e.g., pressing a button to increase or decrease a volume level). The I/O interface 24 may enable electronic device 10 to interface with various other electronic devices, as may the network interface 26. In some embodiments, the I/O interface 24 may include an I/O port for a hardwired connection for charging and/or content manipulation using a standard connector and protocol, such as the Lightning connector, a universal serial bus (USB), or other similar connector and protocol. The network interface 26 may include, for example, one or more interfaces for a personal area network (PAN), such as an ultra-wideband (UWB) or a BLUETOOTH® network, a local area network (LAN) or wireless local area network (WLAN), such as a network employing one of the IEEE 802.11x family of protocols (e.g., WI-FI®), and/or a wide area network (WAN), such as any standards related to the Third Generation Partnership Project (3GPP), including, for example, a 3rd generation (3G) cellular network, universal mobile telecommunication system (UMTS), 4th generation (4G) cellular network, Long Term Evolution® (LTE) cellular network, Long Term Evolution License Assisted Access (LTE-LAA) cellular network, 5th generation (5G) cellular network, and/or New Radio (NR) cellular network, a 6th generation (6G) or greater than 6G cellular network, a satellite network, a non-terrestrial network, and so on. In particular, the network interface 26 may include, for example, one or more interfaces for using a cellular communication standard of the 5G specifications that include the millimeter wave (mmWave) frequency range (e.g., 24.25-300 gigahertz (GHz)) that defines and/or enables frequency ranges used for wireless communication. The network interface 26 of the electronic device 10 may allow communication over the aforementioned networks (e.g., 5G, Wi-Fi, LTE-LAA, and so forth).

The network interface 26 may also include one or more interfaces for, for example, broadband fixed wireless access networks (e.g., WIMAX®), mobile broadband Wireless networks (mobile WIMAX®), asynchronous digital subscriber lines (e.g., ADSL, VDSL), digital video broadcasting-terrestrial (DVB-T®) network and its extension DVB Handheld (DVB-H®) network, ultra-wideband (UWB) network, alternating current (AC) power lines, and so forth. The power source 29 of the electronic device 10 may include any suitable source of power, such as a rechargeable lithium polymer (Li-poly) battery and/or an alternating current (AC) power converter.

As illustrated, the network interface 26 may include a transceiver 30. In some embodiments, all or portions of the transceiver 30 may be disposed within the processor 12. The transceiver 30 may support transmission and receipt of various wireless signals via one or more antennas, and thus may include a transmitter and a receiver. In some embodiments, the transceiver 30 may include phase shifter circuitry. The phase shifter circuitry may include, for example, a first phase shifter circuit and a second phase shifter circuit having non-overlapping boundaries. In some embodiments, the first phase shifter circuit and the second phase shifter circuit may each include two coils forming three inductors. Moreover, the first phase shifter circuit and the second phase shifter circuit may each direct input signals through a number of polygonal conductors of the respective coils that are disposed adjacently or overlaid along multiple planes of a circuit board.

FIG. 2 is a functional diagram of the electronic device 10 of FIG. 1, according to embodiments of the present disclosure. As illustrated, the processor 12, the memory 14, the transceiver 30, a transmitter 52, a receiver 54, and/or antennas 55 (illustrated as 55A-55N, collectively referred to as an antenna 55) may be communicatively coupled directly or indirectly (e.g., through or via another component, a communication bus, a network) to one another to transmit and/or receive signals between one another.

The electronic device 10 may include the transmitter 52 and/or the receiver 54 that respectively enable transmission and reception of signals between the electronic device 10 and an external device via, for example, a network (e.g., including base stations or access points) or a direct connection. As illustrated, the transmitter 52 and the receiver 54 may be combined into the transceiver 30. In some embodiments, the transmitter 52, the receiver 54, or both, may include phase shifter circuitry. In some cases, the phase shifter circuitry may adjust a phase of transmission signals for transmission by antennas 55A-55N. For example, the phase shifter circuitry may adjust a phase of the transmission signals based on a direction of a desired transmission beam. Moreover, the phase shifter circuitry may adjust a phase of received signals by antennas 55A-55N for reception by the processor 12 and/or the memory 14, among other things. For example, the phase shifter circuitry may adjust a phase of the received signals based on a direction of a reception beam associated with the received signals.

As mentioned above, the phase shifter circuitry may include, for example, a first phase shifter circuit and a second phase shifter circuit having non-overlapping boundaries. The first phase shifter circuit and the second phase shifter circuit may each reduce induced currents of the phase shifter circuitry during operation. In some embodiments, the phase shifter circuitry may have reduced insertion loss and/or improved linearity. In some embodiments, the phase shifter circuitry may adjust a phase of the transmission signals and/or reception signals with improved accuracy compared to other phase shifter. Alternatively or additionally, the phase shifter circuitry may have a reduced area compared to other phase shifters, as will be appreciated.

The electronic device 10 may also have the antennas 55A-55N electrically coupled to the transceiver 30. The antennas 55A-55N may be configured in an omnidirectional or directional configuration, in a single-beam, dual-beam, or multi-beam arrangement, and so on. Each antenna 55 may be associated with one or more beams and various configurations. In some embodiments, multiple antennas of the antennas 55A-55N of an antenna group or module may be communicatively coupled to a respective transceiver 30 and each emit radio frequency signals that may constructively and/or destructively combine to form a beam. The electronic device 10 may include multiple transmitters, multiple receivers, multiple transceivers, and/or multiple antennas as suitable for various communication standards. In some embodiments, the transmitter 52 and the receiver 54 may transmit and receive information via other wired or wireline systems or means.

As illustrated, the various components of the electronic device 10 may be coupled together by a bus system 56. The bus system 56 may include a data bus, for example, as well as a power bus, a control signal bus, and a status signal bus, in addition to the data bus. The components of the electronic device 10 may be coupled together or accept or provide inputs to each other using some other mechanism.

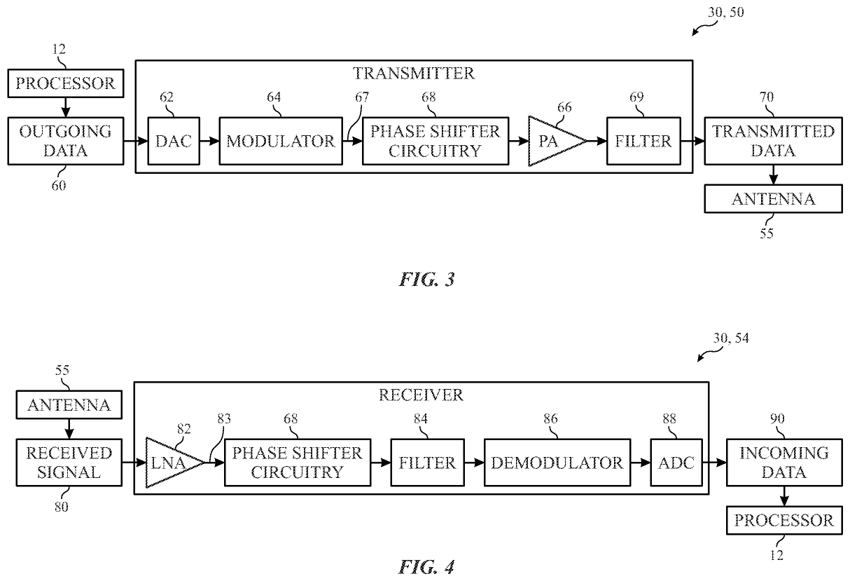

FIG. 3 is a schematic diagram of the transmitter 52 (e.g., transmit circuitry) of the transceiver 30, according to embodiments of the present disclosure. As illustrated, the transmitter 52 may receive outgoing data 60 in the form of a digital signal to be transmitted via the one or more antennas 55. In some embodiments, the transmitter 52 may receive the outgoing data 60 from the processor 12. A digital-to-analog converter (DAC) 62 of the transmitter 52 may convert the digital signal to an analog signal, and a modulator 64 may combine the converted analog signal with a carrier signal to generate a radio wave 67 (e.g., a modulated signal).

In some embodiments, a power amplifier (PA) 66 may be coupled to an output of the modulator 64. In the depicted embodiment, phase shifter circuitry 68 may be coupled to an output of the modulator 64. In some cases, the phase shifter circuitry 68 may adjust a phase of the radio wave 67. For example, the phase shifter circuitry 68 may adjust a phase of the radio wave 67 based on a desired direction or characteristics of a transmission beam. That is, the phase of the radio wave 67 may correspond to a direction of the transmission beam. As such, adjusting the phase of the radio wave 67 may adjust the direction of the transmission beam.

The power amplifier 66 receives the phase shifted radio wave 67 (e.g., the phase shifted and modulated signal) from the phase shifter circuitry 68. The power amplifier 66 may amplify the radio wave 67 to generate amplified signals. The power amplifier 66 may generate the amplified signal to a suitable level to drive transmission of the signal via the one or more antennas 55. It should be appreciated that in alternative or additional embodiments, the phase power amplifier 66 may be disposed before the shifter circuitry 68 and/or after a filter 69, among other possibilities.

The filter 69 (e.g., filter circuitry and/or software) of the transmitter 52 may then remove undesirable noise from the phase shifted amplified radio wave 67 to generate transmitted signal 70 to be transmitted via the one or more antennas 55. The filter 69 may include any suitable filter or filters to remove the undesirable noise from the amplified signal, such as a bandpass filter, a bandstop filter, a low pass filter, a high pass filter, and/or a decimation filter.

The power amplifier 66 and/or the filter 69 may be referred to as part of a radio frequency front end (RFFE), and more specifically, a transmit front end (TXFE) of the electronic device 10. Additionally, the transmitter 52 may include any suitable additional components not shown, or may not include certain of the illustrated components, such that the transmitter 52 may transmit the outgoing data 60 via the one or more antennas 55. For example, the transmitter 52 may include a mixer and/or a digital up converter. As another example, the transmitter 52 may not include the filter 69 if the power amplifier 66 outputs the amplified signal in or approximately in a desired frequency range (such that filtering of the amplified signal may be unnecessary). It should be appreciated that the transceiver 30 may include multiple branches of the transmitter 52, each including similar or different components.

FIG. 4 is a schematic diagram of the receiver 54 (e.g., receive circuitry), according to embodiments of the present disclosure. As illustrated, the receiver 54 may receive received signal 80 from the one or more antennas 55 in the form of an analog signal. A low noise amplifier (LNA) 82 may amplify the received analog signal to generate an amplified received signal 83. In some embodiments, a filter may be coupled to an input of the low noise amplifier (LNA) 82. The amplified received signal 83 may amplify the received analog signal to a suitable level for the receiver 54 to process.

In some cases, the phase shifter circuitry 68 may adjust a phase of the amplified received signal 83. For example, the phase shifter circuitry 68 may adjust a phase of the amplified received signal 83 based on a desired direction or characteristics of a received beam. That is, the phase of the amplified received signal 83 may correspond to a direction of the received beam. As such, adjusting the phase of the amplified received signal 83 may adjust the direction or characteristics of the received beam (e.g., used to receive the received signal 80). It should be appreciated that in alternative or additional embodiments, the phase shifter circuitry 68 may be disposed before the low noise amplifier 82 and/or after a filter 84, among other possibilities.

In some embodiments, the transmitter 52 discussed above and the receiver 54 may include (e.g., share) the phase shifter circuitry 68. Alternatively or additionally, the transmitter 52 may include first phase shifter circuitry 68 and the receiver 54 may include second phase shifter circuitry 68. For example, in some embodiments, the first phase shifter circuitry 68 and the second phase shifter circuitry 68 may include similar circuitry and components.

The filter 84 (e.g., filter circuitry and/or software) may remove undesired noise from the amplified received signal 83, such as cross-channel interference. The filter 84 may also remove additional signals received by the one or more antennas 55 that are at frequencies other than the desired signal. The filter 84 may include any suitable filter or filters to remove the undesired noise or signals from the received signal, such as a bandpass filter, a bandstop filter, a low pass filter, a high pass filter, and/or a decimation filter. The low noise amplifier 82 and/or the filter 84 may be referred to as part of the RFFE, and more specifically, a receiver front end (RXFE) of the electronic device 10.

A demodulator 86 may remove a radio frequency carrier signal and/or extract a demodulated signal (e.g., an envelope signal) from the filtered signal for processing. An analog-to-digital converter (ADC) 88 may receive the demodulated analog signal and convert the signal to a digital signal of incoming data 90 to be further processed by the electronic device 10. Additionally, the receiver 54 may include any suitable additional components not shown, or may not include certain of the illustrated components, such that the receiver 54 may receive the received signal 80 via the one or more antennas 55. For example, the receiver 54 may include a mixer and/or a digital down converter. It should be appreciated that the transceiver 30 may include multiple branches of the receiver 54, each including similar or different components.

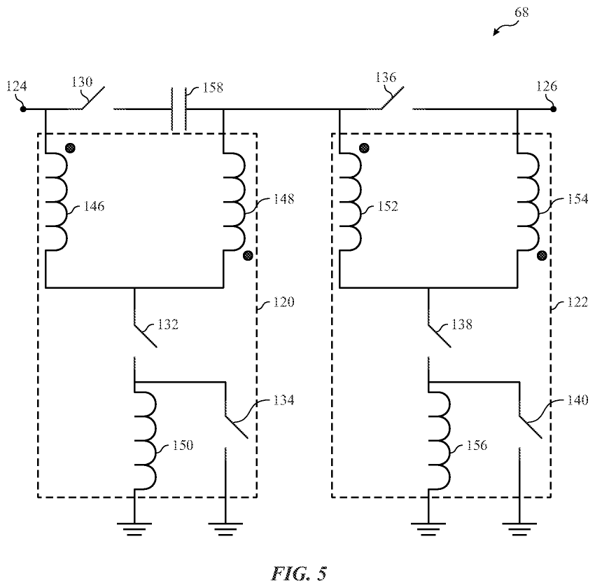

FIG. 5 is a schematic diagram of the phase shifter circuitry 68, according to embodiments of the present disclosure. As mentioned above, the transceiver 30 may include the phase shifter circuitry 68. The phase shifter circuitry 68 may include a first phase shifter circuit 120 and a second phase shifter circuit 122. The first phase shifter circuit 120 may shift (e.g., delay) the phase of input signals by a first phase shift value (e.g., −25° or less, −47 or less, −65° or less, −90° or less, −98° or less, −90° or more, and so on, among other possibilities). Moreover, the second phase shifter circuit 122 may shift (e.g., delay) the phase of the input signals by a second phase shift value (e.g., −25° or less, −32° or less, −39° or less, −45° or less, −52° or less, −45° or more, and so on, among other possibilities).

The first phase shifter circuit 120 may have a first terminal 124. The first phase shifter circuit 120 may be coupled to the second phase shifter circuit 122. Moreover, the second phase shifter circuit 122 may have a second terminal 126. In some embodiments, the phase shifter circuitry 68 may receive the input signals from the first terminal 124. In alternative or additional embodiments, the phase shifter circuitry 68 may receive the input signals from the second terminal 126. The input signals may include the radio wave 67, the amplified signal, and/or the amplified received signal 83 discussed above, among other possibilities. Similarly, the first terminal 124 and the second terminal 126 may output signals by the first terminal 124 and/or the second terminal 126. The output signals may include the radio wave 67, the amplified signal, and/or the amplified received signal 83, as adjusted.

The first phase shifter circuit 120 may include a first switch 130, a second switch 132, and a third switch 134. The first phase shifter circuit 120 may include a first inductor 146 (L1) and a second inductor 148 (L2) coupled to the first switch 130 and the second switch 132. The first inductor 146 may be coupled to the first terminal 124. In the depicted embodiment, the second inductor 148 may be coupled to the first switch 130 via a capacitor 158. The first inductor 146 and the second inductor 148 may have different or opposite polarities. Moreover, the first inductor 146 and the second inductor 148 may be coupled in parallel when the first switch 130 is closed.

The first inductor 146 and the second inductor 148 may be coupled to a third inductor 150 (L3) via the second switch 132. The third inductor 150 may be coupled to the second switch 132 and the third switch 134 on one end and to a ground connection on a second end. The third inductor 150 may be coupled to the first inductor 146 and the second inductor 148 via the second switch 132 and may be coupled to the ground connection via the third switch 134. The third switch 134 may close (e.g., activate) and/or the second switch may open (e.g., deactivate) to couple the third inductor 150 to the ground connection and therefore bypass the third inductor 150.

The first switch 130 may be open, the second switch 132 may be open, and the third switch 134 may be closed to adjust a phase of the input signals by the first phase shift value. The first switch 130 may be closed, the second switch 132 may be closed, and the third switch 134 may be open to bypass the first phase shifter circuit 120. As such, the first phase shifter circuit 120 may be coupled to the second phase shifter circuit 122 via the first switch 130 and the capacitor 158.

Moreover, the second phase shifter circuit 122 may include a fourth switch 136, a fifth switch 138, and a sixth switch 140. The second phase shifter circuit 122 may include a fourth inductor 152 (L4) and a fifth inductor 154 (L5) coupled to the fourth switch 136 and the fifth switch 138. The fifth inductor 154 may be coupled to the second terminal 126. The fourth inductor 152 and the fifth inductor 154 may have different or opposite polarities. Moreover, the fourth inductor 152 and the fifth inductor 154 may be coupled in parallel when the fourth switch 136 is closed.

The fourth inductor 152 and the fifth inductor 154 may be coupled to a sixth inductor 156 (L6) via the fifth switch 138. The sixth inductor 156 may be coupled to the fifth switch 138 and the sixth switch 140 on one end and to the ground connection on a second end. The sixth inductor 156 may be coupled to the first inductor 146 and the second inductor 148 via the fifth switch 138 and may be coupled to the ground connection via the sixth switch 140. The sixth switch 140 may close (e.g., activate) and/or the fifth switch may open (e.g., deactivate) to couple the sixth inductor 156 to the ground connection and therefore bypass the sixth inductor 156.

The fourth switch 136 may be open, the fifth switch 138 may be open, and the sixth switch 140 may be closed to adjust a phase of the input signals by the second phase shift value. The fourth switch 136 may be closed, the fifth switch 138 may be closed, and the sixth switch 140 may be open to bypass the second phase shifter circuit 122. As such, the phase shifter circuitry 68 may adjust a phase of the input signals by the first phase shift value, the second phase shift value, or both. The processor 12 discussed above, or any other viable component may generate control signals to open and close the switches 130, 132, 134, 136, 138, and 140.

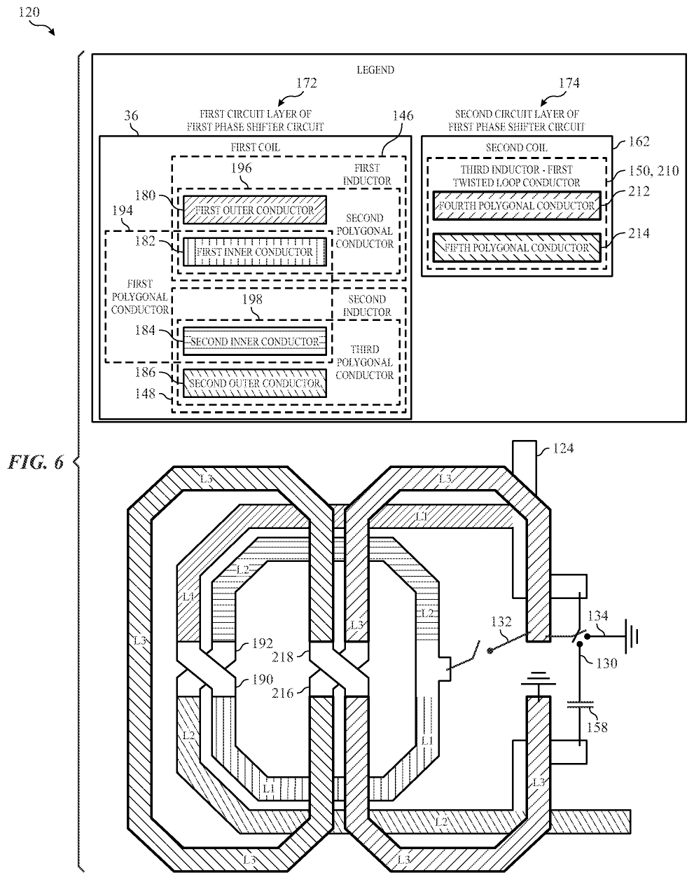

FIG. 6 is a layout 160 of the first phase shifter circuit 120 of the phase shifter circuitry 68, according to embodiments of the present disclosure. The first phase shifter circuit 120 may include a first coil 162 and a second coil 164. The first coil 162 may form the first inductor 146 (L1) and the second inductor 148 (L2). Moreover, the second coil 164 may form the third inductor 150 (L3), as will be appreciated. As mentioned above, the first phase shifter circuit 120 may shift (e.g., delay) the phase of the input signals by a first phase shift value (e.g., −25°, −47, −65°, −90°, −98°, and so, among other possibilities).

The first coil 162 may be disposed on a first circuit layer 172 (e.g., a first plane surface) of the phase shifter circuitry 68. The second coil 164 may be disposed on a second circuit layer 174 (e.g., a second plane surface) of the phase shifter circuitry 68. The first circuit layer 172 may be disposed over or under, and in proximity of (e.g., adjacent to) the second circuit layer 174. For example, the first circuit layer 172 and the second circuit layer 174 may each be disposed on different circuit layers of a printed circuit board (PCB), among other possibilities.

The first coil 162 may include a first outer conductor 180, a first inner conductor 182, a second inner conductor 184, and a second outer conductor 186. The conductors 180, 182, 184, and 186 may each form a portion of a respective polygonal shape, as discussed herein. The first outer conductor 180 may be coupled to the first terminal 124 of the phase shifter circuitry 68. Moreover, the second outer conductor 186 may be coupled to the second phase shifter circuitry 68. As mentioned above, in some embodiments, the first phase shifter circuit 120 may receive input signals from the first terminal 124. In alternative or additional embodiments, the first phase shifter circuit 120 may receive input signals from the second phase shifter circuitry 68.

In some embodiments, the first outer conductor 180 may be disposed at least partially symmetrical to the second outer conductor 186. The first outer conductor 180 may be disposed in proximity of (e.g., adjacent to) and around the second inner conductor 184 on the first circuit layer 172. That is, the first outer conductor 180 may be disposed circularly outside of (e.g., around) and partially surrounding the second inner conductor 184.

Similarly, the second outer conductor 186 may be disposed in proximity of (e.g., adjacent to) and around the first inner conductor 182 on the first circuit layer 172. That is, the second outer conductor 186 may be disposed concentrically outside of (e.g., around) and partially surrounding the first inner conductor 182. The first inner conductor 182 and the second inner conductor 184 may be coupled to and disposed between the first outer conductor 180 and the second outer conductor 186.

As such, the first outer conductor 180 may be coupled to the second outer conductor 186 via the first inner conductor 182 and the second inner conductor 184. In some embodiments, the first outer conductor 180 may also be coupled to the second outer conductor 186 via the first switch 130 and the capacitor 158. As mentioned above, the first switch 130 may close to bypass the phase shifter circuitry 68 by coupling the first terminal 124 to the second phase shifter circuitry 68.

The first inner conductor 182 may be coupled to the first outer conductor 180 by a first connector 190. The second inner conductor 184 may be coupled to the second outer conductor by a second connector 192 cross-coupled over or under the first connector 190. Moreover, the first inner conductor 182 may be coupled to the second inner conductor 184 to form a first polygonal conductor 194. As such, the first polygonal conductor 194 may be disposed between and/or twisted inside the first outer conductor 180 and the second outer conductor 186.

The first coil 162 may include the first connector 190, the second connector 192, or both. The first connector 190 may be disposed (e.g., crossed) over or under the second connector 192 across multiple circuit layers to cross-couple the outer conductors 180 and 186 to the inner conductors 182 and 184. In specific embodiments, the first connector 190 and the second connector 192 may each be disposed on and/or in-between the first circuit layer 172 and/or the second circuit layer 174, among other possibilities.

In the depicted embodiment, the first polygonal conductor 194 may be enclosed (e.g., encircled) by the first outer conductor 180 and the second outer conductor 186. A polygonal conductor, such as the first polygonal conductor 194, may have any viable polygonal shape and/or symmetrical polygonal shape, among other things. For example, the first polygonal conductor 194, including the first inner conductor 182 and the second inner conductor 184, may have a circular shape, a pentagonal shape, an octagonal shape, a hexagonal shape, among other possibilities.

In some embodiments, the first outer conductor 180 and the second outer conductor 186 may be symmetrical or at least partially symmetrical. Moreover, the first outer conductor 180 may be disposed around the second inner conductor 184 and the second outer conductor 186 may be disposed around the first inner conductor 182. In some embodiments, the first outer conductor 180 and the first inner conductor 182 may form at least a part of a second polygonal conductor 196 (e.g., a symmetrical polygonal conductor). The first inductor 146 may include the second polygonal conductor 196 including the first outer conductor 180 and the first inner conductor 182.

Similarly, the second outer conductor 186 and the second inner conductor 184 may form at least a part of a third polygonal conductor 198 (e.g., a symmetrical polygonal conductor). The second inductor 148 may include the third polygonal conductor 198 including the second outer conductor 186 and the second inner conductor 184. In the depicted embodiment, a first area associated with the first inductor 146 may at least partially overlap with a second area associated with the second inductor 148. The first area may be partially enclosed by the second polygonal conductor 196. Moreover, the second area may be partially enclosed by the third polygonal conductor 198. As such, the first inductor 146 and the second inductor 148 may be at least partially intertwined.

The first inductor 146 may be coupled to the first terminal 124 and the second inductor 148. Moreover, the second inductor 148 may be coupled to the first inductor 146 and the second phase shifter circuit 122. As mentioned above, the first inductor 146 of the first phase shifter circuit 120 may receive input signals from the first terminal 124 and provide output signals to the second phase shifter circuitry 68. Alternatively or additionally, the second inductor 148 of the first phase shifter circuit 120 may receive the input signals from the second phase shifter circuitry 68 and provide the output signals to the first terminal 124.

The second coil 164 may include a first twisted loop conductor 210 having a figure-eight shape. The first twisted loop conductor 210 may include a fourth polygonal conductor 212 (e.g., a symmetrical polygonal conductor) and a fifth polygonal conductor 214 (e.g., a symmetrical polygonal conductor). The fourth polygonal conductor 212 may be cross-coupled to the fifth polygonal conductor 214 (e.g., a symmetrical polygonal conductor).

The fourth polygonal conductor 212 and the fifth polygonal conductor 214 may each have a circular shape, a pentagonal shape, an octagonal shape, and/or a hexagonal shape, among other possibilities. The third inductor 150 may include the fourth polygonal conductor 212 and the fifth polygonal conductor 214.

The fourth polygonal conductor 212 may be cross-coupled to the fifth polygonal conductor 214 by a third connector 216 and a fourth connector 218. The second coil 164 may include the third connector 216, the fourth connector 218, or both. The third connector 216 may be disposed (e.g., crossed) over or under the fourth connector 218 across multiple circuit layers to cross-couple the fourth polygonal conductor 212 to the fifth polygonal conductor 214. In specific embodiments, the third connector 216 and the fourth connector 218 may each be disposed on and/or in-between the first circuit layer 172 and/or the second circuit layer 174, among other possibilities. As such, the second coil 164 may form the first twisted loop conductor 210 based on cross-coupling the fourth polygonal conductor 212 to the fifth polygonal conductor 214.

The second coil 164 may have a first input port and a first output port on the fourth polygonal conductor 212. The first output port of the second coil 164 may be coupled to a ground connection. The first input port may be coupled to an intersection of the first inner conductor 182 and the second inner conductor 184 of the first coil 162. In specific embodiments, the first inner conductor 182 may be split from the second inner conductor 184 at a coupling point of the first input port.

In some embodiments, the first input port may be coupled to the intersection of the first inner conductor 182 and the second inner conductor 184 via a second switch 132. The second switch 132 may couple and uncouple the first coil 162 and the second coil 164. As such, the second switch 132 may open to bypass the second coil 164. The second switch 132 may be disposed on and/or in-between the first circuit layer 172 and/or the second circuit layer 174, among other possibilities. In some embodiments, the first input port may also be coupled to the ground connection via a third switch 134. As such, the third switch 134 may close to couple the second coil 164 to the ground connection and therefore bypass the second coil 164.

With the foregoing in mind, the third inductor 150 may receive at least a portion of the input signals. As mentioned above, the third inductor 150 may receive at least a portion of the input signals based on the first switch 130 being open, the second switch 132 being closed, and the third switch 134 being open. The fourth polygonal conductor 212 and the fifth polygonal conductor 214 may direct the portion of the input signals in opposite directions based on being cross-coupled and having the figure-eight shape.

In some cases, directing the input signals in the opposite directions through the adjacent polygonal conductors 212 and 214 of the second coil 164 may reduce induced currents of the first phase shifter circuit 120 during operation. For example, in specific cases, at least a part of the induced currents of the polygonal conductors 212 and 214 may destructively combine during operation.

Moreover, in the depicted embodiment, the second coil 164 may be disposed on the second circuit layer 174 overlaid on and at least partially extended around (e.g., outside) a boundary of the first coil 162 on the first circuit layer 172. For example, the first twisted loop conductor 210 may have a second boundary that covers (e.g., substantially covers) a first boundary of the first coil 162. In some cases, the first inductor 146 and the second inductor 148 disposed on the first circuit layer 172 may reduce induced currents of the third inductor 150 disposed on the second circuit layer 174 during operation.

Similarly, the third inductor 150 may reduce induced currents of the first inductor 146 and the second inductor 148 during operation. For example, in specific cases, at least a part of the induced currents of the inductors 146, 148, and 150 may destructively combine during operation. It should be appreciated that in alternative or additional embodiments, the first coil 162 may be overlaid on and at least partially extended around (e.g., outside) the boundary of the second coil 164.

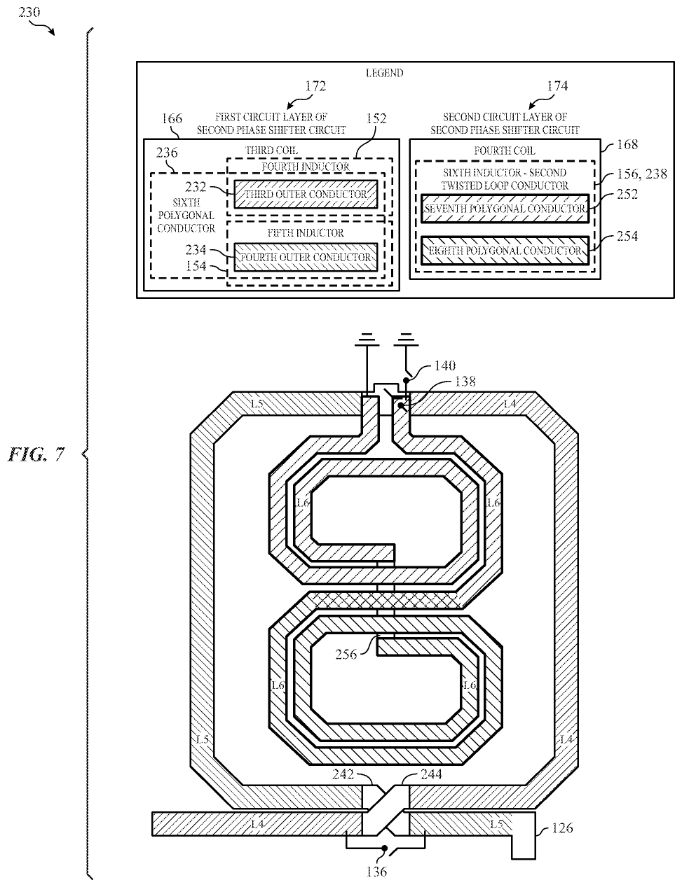

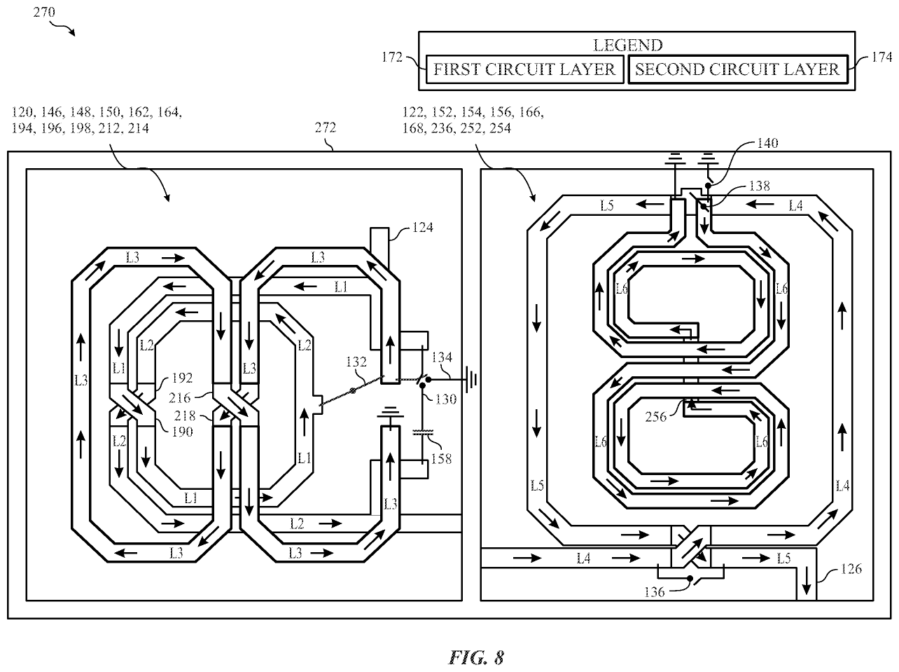

FIG. 7 is a layout 230 of the second phase shifter circuit 122 of the phase shifter circuitry 68, according to embodiments of the present disclosure. The second phase shifter circuit 122 may include a third coil 166 and a fourth coil 168. As mentioned above, the second phase shifter circuit 122 may shift (e.g., delay) the phase of the input signals by a second phase shift value (e.g., −25°, −32°, −39°, −45°, −52°, and so, among other possibilities). The third coil 166 may form the fourth inductor 152 (L4) and the fifth inductor 154 (L5). Moreover, the fourth coil 168 may form the sixth inductor 156 (L6).

The third coil 166 may be disposed on the first circuit layer 172 (e.g., the first plane surface) of the phase shifter circuitry 68. The fourth coil 168 may be disposed on the second circuit layer 174 (e.g., the second plane surface) of the phase shifter circuitry 68. As mentioned above, the first circuit layer 172 may be disposed over or under, and in proximity of (e.g., adjacent to) the second circuit layer 174.

The third coil 166 may include a third outer conductor 232 and a fourth outer conductor 234 forming a sixth polygonal conductor 236 (e.g., a symmetrical polygonal conductor). In some embodiments, the third outer conductor 232 and the fourth outer conductor 234 may each form a respective portion of the sixth polygonal conductor 236. The third outer conductor 232 may be twisted over or under the fourth outer conductor 234 to form the sixth polygonal conductor 236. The sixth polygonal conductor 236 may form a circular shape, a pentagonal shape, an octagonal shape, a hexagonal shape, among other possibilities.

In some cases, the fourth coil 168 may couple to an intersection of the third outer conductor 232 and the fourth outer conductor 234. The fourth coil 168 may include a second twisted loop conductor 238 disposed between, enclosed by (e.g., encircled by), and/or coupled to the third outer conductor 232 and the fourth outer conductor 234, as will be appreciated.

In some embodiments, the third outer conductor 232 may be coupled to the second outer conductor 186 of the first coil discussed above. Moreover, the fourth outer conductor 234 may be coupled to the second terminal 126. As such, in some cases, the second phase shifter circuit 122 may receive input signals from the second terminal 126. Alternatively of additionally, the second phase shifter circuit 122 may receive input signals from the first phase shifter circuitry 68.

The fourth inductor 152 may include a portion of the sixth polygonal conductor 236 including the third outer conductor 232. The fifth inductor 154 may include a remaining portion of the sixth polygonal conductor 236 including the fourth outer conductor 234. In the depicted embodiment, a third area associated with the fourth inductor 152 may at least partially overlap with a fourth area associated with the fifth inductor 154. The third area may be partially enclosed by the third outer conductor 232. Moreover, the fourth area may be partially enclosed by the fourth outer conductor 234. As such, the fourth inductor 152 and the fifth inductor 154 may be at least partially intertwined.

In some embodiments, the third outer conductor 232 may include a fifth connector 242 and the fourth outer conductor 234 may include a sixth connector 244. For example, the fifth connector 242 may be disposed (e.g., crossed) over or under the sixth connector 244 across multiple circuit layers to twist the third outer conductor 232 over or under the fourth outer conductor 234. In specific embodiments, the fifth connector 242 and the sixth connector 244 may each be disposed on and/or in-between the first circuit layer 172 and/or the second circuit layer 174, among other possibilities.

In alternative or additional embodiments, the third outer conductor 232 may be coupled to the fourth outer conductor 234 via a fourth switch 136. The fourth switch 136 may couple and uncouple an input/output portion of the third outer conductor 232 to an input/output portion of the fourth outer conductor 234. For example, the fourth switch 136 may couple and uncouple the second outer conductor 186 of the first coil discussed above to the second terminal 126. As such, the fourth switch 136 may open to bypass the third coil 166. The fourth switch 136 may be disposed on and/or in-between the first circuit layer 172 and/or the second circuit layer 174, among other possibilities.

The fourth coil 168 may include a second twisted loop conductor 238 having a figure-eight shape. The second twisted loop conductor 238 may include a seventh polygonal conductor 252 (e.g., a symmetrical polygonal conductor) cross-coupled to an eighth polygonal conductor 254 (e.g., a symmetrical polygonal conductor). For example, the seventh polygonal conductor 252 and the eighth polygonal conductor 254 may each have a circular shape, a pentagonal shape, an octagonal shape, and/or a hexagonal shape, among other possibilities. The sixth inductor 156 may include the seventh polygonal conductor 252 and the eighth polygonal conductor 254.

In some embodiments, the seventh polygonal conductor 252 and the eighth polygonal conductor 254 may share a portion of the respective conductors. Moreover, the seventh polygonal conductor 252 may be cross-coupled to the eighth polygonal conductor 254 by a seventh connector 256. In some embodiments, the fourth coil 168 may include the seventh connector 256. The seventh connector 256 may be disposed (e.g., crossed) over or under a portion of the seventh polygonal conductor 252 and the eighth polygonal conductor 254.

The seventh connector 256 may be disposed across multiple circuit layers to cross-couple the seventh polygonal conductor 252 to the eighth polygonal conductor 254. In specific embodiments, the seventh connector 256 may be disposed on and/or in-between the first circuit layer 172 and/or the second circuit layer 174, among other possibilities. As such, the fourth coil 168 may form the second twisted loop conductor 238 based on cross-coupling the seventh polygonal conductor 252 to the eighth polygonal conductor 254.

The seventh polygonal conductor 252 may have a second input port and a second output port. The second output port may be coupled to a ground connection. The second input port may be coupled to the intersection of the third outer conductor 232 and the fourth outer conductor 234 of the third coil 166. In some embodiments, the third outer conductor 232 may be split from the fourth outer conductor 234 at a coupling point of the second input port.

In some embodiments, the second input port may be coupled to the intersection of the third outer conductor 232 and the fourth outer conductor 234 via a fifth switch 138. The fifth switch 138 may couple and uncouple the third coil 166 and the fourth coil 168. The fifth switch 138 may open to bypass the fourth coil 168. The fifth switch 138 may be disposed on and/or in-between the first circuit layer 172 and/or the second circuit layer 174, among other possibilities. In some embodiments, the second input port may also be coupled to the ground connection via a sixth switch 140. As such, the sixth switch 140 may close to couple the fourth coil 168 to the ground connection and therefore bypass the fourth coil 168.

The third outer conductor 232 and the fourth outer conductor 234 may be disposed in proximity of (e.g., adjacent to) and around the second twisted loop conductor 238. The third outer conductor 232 and the fourth outer conductor 234 may be disposed circularly outside of and partially surrounding the second twisted loop conductor 238. For example, the third coil 166 may be extended around boundaries of the second twisted loop conductor 238. It should be appreciated that in alternative or additional embodiments, the second twisted loop conductor 238 may be disposed circularly outside of and partially surrounding the third outer conductor 232 and the fourth outer conductor 234. For example, the second twisted loop conductor 238 may be extended around boundaries of the third coil 166.

With the foregoing in mind, the sixth inductor 156 may receive at least a portion of the input signals. As mentioned above, the sixth inductor 156 may receive at least a portion of the input signals based on the fourth switch 136 being open, the fifth switch 138 being closed, and the sixth switch 140 being open. The seventh polygonal conductor 252 and the eighth polygonal conductor 254 may be cross-coupled and have a figure-eight shape to direct the portion of the input signals in opposite directions.

In some cases, directing the input signals in the opposite directions through the adjacent polygonal conductors 252 and 254 of the fourth coil 168 may reduce induced currents of the second phase shifter circuit 122 during operation. For example, in some cases, at least a part of the induced currents of the polygonal conductors 252 and 254 may destructively combine during operation.

Moreover, in the depicted embodiment, the third coil 166 may be disposed on the first circuit layer 172 overlaid on and at least partially extended around (e.g., outside) a boundary of the fourth coil 168 on the second circuit layer 174. In some cases, the fourth inductor 152 and the fifth inductor 154 disposed on the first circuit layer 172 may reduce induced currents of the sixth inductor 156 disposed on the second circuit layer 174 during operation.

Similarly, the sixth inductor 156 may reduce induced currents of the fourth inductor 152 and the fifth inductor 154 during operation. For example, in some cases, at least a part of the induced currents of the inductors 152, 154, and 156 may destructively combine during operation. It should be appreciated that in alternative or additional embodiments, the fourth coil 168 may be overlaid on and at least partially extended around (e.g., outside) the boundary of the third coil 166.

FIG. 8 is a layout 270 of the phase shifter circuitry 68 including the first phase shifter circuit 120 and the second phase shifter circuit 122, according to embodiments of the present disclosure. The first phase shifter circuit 120 and the second phase shifter circuit 122 may be coupled to a ring guard 272. As discussed above, the first phase shifter circuit 120 may include a first coil 162 and a second coil 164. Moreover, the second phase shifter circuit 122 may include a third coil 166 and a fourth coil 168.

The third coil 166 and the fourth coil 168 may be disposed adjacent to and not having an overlapping boundary with the first coil 162 and the second coil 164. In some embodiments, the second coil 164 may be disposed and/or extended at a different direction compared to (e.g., orthogonal to, nearly orthogonal to) the fourth coil 168. For example, the fourth polygonal conductor 212 and the fifth polygonal conductor 214 of the second coil 164 may be extended along a first direction. In specific embodiments, the seventh polygonal conductor 252 and the eighth polygonal conductor 254 of the fourth coil 168 may be extended along a second direction perpendicular to (e.g., nearly perpendicular to) the first direction.

In the depicted embodiment, the phase shifter circuitry 68 may receive the input signals at the first terminal 124. It should be appreciated that in alternative or additional cases, the phase shifter circuitry 68 may receive the input signals at the second terminal 126. Moreover, the first switch 130 is open, the second switch 132 is open, and the third switch 134 is closed. As such, the fourth polygonal conductor 212 and the fifth polygonal conductor 214 may direct the portion of the input signals in opposite directions based on being cross-coupled and having the figure-eight shape. Furthermore, the fourth switch 136 is open, the fifth switch 138 is open, and the sixth switch 140 is closed. Accordingly, the seventh polygonal conductor 252 and the eighth polygonal conductor 254 may be cross-coupled and have a figure-eight shape to direct the portion of the input signals in opposite directions.

As mentioned above, directing the input signals in the opposite directions through the adjacent polygonal conductors 212 and 214 of the second coil 164 may reduce induced currents of the first phase shifter circuit 120 during operation. Similarly, in some cases, directing the input signals in the opposite directions through the adjacent polygonal conductors 252 and 254 of the fourth coil 168 may reduce induced currents of the second phase shifter circuit 122 during operation. For example, in specific cases, at least a part of the induced currents of the inductors 146, 148, 150, 152, 154, and 156 may destructively combine during operation.

In some cases, directing the input signals in the opposite directions through the adjacent and polygonal conductors 212 and 214 of the second coil 164 and the adjacent and polygonal conductors 252 and 254 of the fourth coil 168 may reduce induced currents of the phase shifter circuitry 68 during operation. For example, the orthogonal disposition of the polygonal conductors 212 and 214 of the second coil 164 compared to the polygonal conductors 252 and 254 of the fourth coil 168 may increase a distance between the polygonal conductors 212, 214, 252 and 254.

As such, in some cases, an accumulation of the induced currents of the polygonal conductors 212, 214, 252 and 254 may be reduced based on the increased distance between the polygonal conductors 212, 214, 252 and 254. In specific cases, at least a portion of the induced currents of the polygonal conductors 212, 214, 252 and 254 may destructively combine to reduce the induced currents of the phase shifter circuitry 68 during operation. Moreover, an undesired effect of the inductors 146, 148, 150, 152, 154, and/or 156 on each other or one or more other components of the electronic device 10 including the phase shifter circuitry 68 may be reduced during operation.

Furthermore, the phase shifter circuitry 68 may have reduced insertion loss based on the reduction of the induced currents. In some cases, the phase shifter circuitry 68 may output signals with improved linearity based on the reduced induced currents. Moreover, the phase shifter circuitry 68 may have a reduced area compared to other phase shifters. For example, the phase shifter circuitry 68 may have a 40 percent, 43 percent, 56 percent, 60 percent, 75 percent, and so on, among other possibilities of percentages of reduced area compared to other phase shifter circuitries.

It is well understood that the use of personally identifiable information should follow privacy policies and practices that are generally recognized as meeting or exceeding industry or governmental requirements for maintaining the privacy of users. In particular, personally identifiable information data should be managed and handled so as to minimize risks of unintentional or unauthorized access or use, and the nature of authorized use should be clearly indicated to users.

The specific embodiments described above have been shown by way of example, and it should be understood that these embodiments may be susceptible to various modifications and alternative forms. It should be further understood that the claims are not intended to be limited to the particular forms disclosed, but rather to cover all modifications, equivalents, and alternatives falling within the spirit and scope of this disclosure.

The techniques presented and claimed herein are referenced and applied to material objects and concrete examples of a practical nature that demonstrably improve the present technical field and, as such, are not abstract, intangible or purely theoretical. Further, if any claims appended to the end of this specification contain one or more elements designated as “means for [perform]ing [a function] . . . ” or “step for [perform]ing [a function] . . . ”, it is intended that such elements are to be interpreted under 35 U.S.C. 112(f). However, for any claims containing elements designated in any other manner, it is intended that such elements are not to be interpreted under 35 U.S.C. 112(f).

What is claimed is:

1. Phase shifter circuitry comprising:
a first phase shifter circuit comprising a first coil and a second coil, the second coil being disposed over and extended around a boundary of the first coil, the second coil comprising a first twisted loop conductor extended in a first direction; and
a second phase shifter circuit comprising a third coil and a fourth coil, the fourth coil being disposed over and enclosed by a boundary of the third coil, the fourth coil comprising a second twisted loop conductor extended in a second direction different than the first direction.

2. The phase shifter circuitry of claim 1, wherein the first twisted loop conductor and the second twisted loop conductor each comprises a plurality of cross-coupled polygonal conductors forming a figure-eight shape.

3. The phase shifter circuitry of claim 1, wherein the first phase shifter circuit comprises a first switch configured to couple a first terminal of the first phase shifter circuit to the second phase shifter circuit, and a second switch configured to bypass the second phase shifter circuit.

4. The phase shifter circuitry of claim 3, wherein processing circuitry coupled to the phase shifter circuitry is configured to close the first switch to bypass the first phase shifter circuit, and close the second switch to bypass the second phase shifter circuit.

5. The phase shifter circuitry of claim 1, wherein the phase shifter circuitry is configured to adjust a phase of a first signal before being transmitted by an antenna, and adjust a phase of a second signal after being received by the antenna.

6. The phase shifter circuitry of claim 1, wherein the third coil and the fourth coil do not overlap with the first coil and the second coil.

7. Phase shifter circuitry comprising:
a first coil disposed on a first circuit layer and having a first boundary, comprising
a first polygonal conductor comprising a first inner conductor coupled to a second inner conductor, and
a second polygonal conductor comprising a first outer conductor coupled to a second outer conductor, the first outer conductor being coupled to the first inner conductor, and the second outer conductor coupled to the second inner conductor, the first polygonal conductor being encircled by the second outer conductor,
a second coil disposed on a second circuit layer, the second coil being coupled to the first inner conductor and the second inner conductor, the second coil comprising a first twisted loop conductor having a second boundary that covers the first boundary of the first coil,
a third coil disposed on the first circuit layer, the third coil being coupled to the second outer conductor, the third coil not overlapping with the first coil and the second coil; and
a fourth coil coupled to the third coil, the fourth coil comprising a second twisted loop conductor encircled by the third coil, and the second twisted loop conductor being disposed in a different direction with respect to the first twisted loop conductor.

8. The phase shifter circuitry of claim 7, wherein the first outer conductor is disposed around the second inner conductor and the second outer conductor is disposed around the first inner conductor.

9. The phase shifter circuitry of claim 7, wherein the first twisted loop conductor comprises a third polygonal conductor cross-coupled to a fourth polygonal conductor.

10. The phase shifter circuitry of claim 7, wherein the third coil comprises a third outer conductor and a fourth outer conductor, the fourth coil being coupled to an intersection of the third outer conductor and the fourth outer conductor.

11. The phase shifter circuitry of claim 10, wherein the fourth coil is disposed on the second circuit layer.

12. The phase shifter circuitry of claim 7, wherein the second twisted loop conductor comprises a third polygonal conductor cross-coupled to a fourth polygonal conductor.

13. The phase shifter circuitry of claim 7, wherein the first twisted loop conductor and the second twisted loop conductor each comprises a plurality of interconnected polygonal conductors forming a figure-eight shape.

14. The phase shifter circuitry of claim 7, wherein the first twisted loop conductor is extended perpendicularly with respect to the second twisted loop conductor.

15. The phase shifter circuitry of claim 7, comprising a first switch configured to couple a first terminal of the phase shifter circuitry to the third coil bypassing the first coil and the second coil, or a second switch configured to couple a second terminal of the phase shifter circuitry to the first coil bypassing the third coil and the fourth coil.

16. An electronic device comprising:
processing circuitry;
an antenna; and
phase shifter circuitry coupled to the antenna and the processing circuitry, the phase shifter circuitry comprising
a first coil,
a second coil coupled to the first coil, the second coil being disposed over and extending around the first coil, the second coil comprising a first twisted loop conductor extended in a first direction,
a third coil coupled to the first coil, the third coil not overlapping with the first coil and the second coil, and
a fourth coil coupled to the third coil, the fourth coil being disposed over and surrounded by the third coil, the fourth coil comprising a second twisted loop conductor extending in a second direction different than the first direction.

17. The electronic device of claim 16, comprising a first switch configured to couple a first terminal of the phase shifter circuitry to the third coil bypassing the first coil and the second coil, and a second switch configured to couple a second terminal of the phase shifter circuitry to the first coil bypassing the third coil and the fourth coil.

18. The electronic device of claim 17, wherein the processing circuitry is configured to close the first switch to bypass the first coil and the second coil, and close the second switch to bypass the third coil and the fourth coil.

19. The electronic device of claim 16, wherein the phase shifter circuitry is configured to adjust a phase of a first signal before being transmitted by the antenna, and adjust a phase of a second signal before being received by the antenna.

20. The electronic device of claim 19, wherein the processing circuitry is configured to generate the first signal, and receive the second signal.
